(19) United States
(12) Patent Application Publication
(10) Pub. No.: US 2023/0006628 A1
(43) Pub. Date: Jan. 5, 2023

(54) AMPLITUDE LIMITING CIRCUIT FOR SOUND SIGNAL

(71) Applicant: Kenichi OSHIMA, Tokyo (JP)

(72) Inventor: Kenichi OSHIMA, Tokyo (JP)

(21) Appl. No.: 17/674,141

(22) Filed: Feb. 17, 2022

(30) Foreign Application Priority Data
Jun. 30, 2021 (JP) 2021-109037

(51) Int. Cl. H03G 11/04; H03G 9/18

(52) U.S. Cl. CPC H03G 11/04; H03G 9/18

(57) ABSTRACT

Equipment that can comfortably hear mixed large sound and small sound at the same time by earphones and headphones is achieved. Level of rise and fall of an input signal waveform is logarithmically compressed and output to limit wave height, and an output signal is taken out from a wave-height-limited signal by eliminating or attenuating harmonic distortion. A limiter 6 limits an amplitude of an input sound signal. The integrator 7 is connected to the output-side of the limiter 6 and logarithmically compresses rise or fall of an output signal waveform from the limiter 6.

### CROSS-REFERENCE TO RELATED APPLICATION

This application is based upon and claims the benefit of priority from Japan Patent Application No. 2010-29926, filed on Feb. 15, 2010, the entire contents of which are incorporated herein by reference.

### FIELD OF INVENTION

The present disclosure relates to an amplitude limiting circuit for sound signal applicable to audio equipment such as hearing aids, headphones, and earphones, etc.

### BACKGROUND

There is a large difference between sound heard in natural environment and sound recorded by microphones and reproduced, because properties of audio equipment does not match human ears. Therefore, it has been a dream for one skilled in the art to achieve audio equipment that can reproduce natural sound.

In addition, although small sound equipment cannot reproduce large sound, there is a demand of small products that can reproduce larger sound.

Furthermore, it had been considered impossible to create hearing aids that enable severe hearing-impaired to clearly hear languages. In the conventional hearing aids, when volume of sound is made larger so that the severe hearing-impaired can hear small sound, large sound also becomes larger at the same rate, putting a heavy burden on ears. Moreover, pressure in earholes increase by sound output from earphones, making said problem even larger.

Although sound waves emitted from earphones should spread around, they actually do not because earholes are blocked by earphones. Therefore, sound pressure in the earholes further increases by the sound from earphones. Since excessively large portion in a waveform of large sound must be cut, the sound sound wave loss of part of the sound, making it hard to distinguish language. This is mostly the reason why the sever hearing-impaired cannot hear language by the conventional hearing aid, and a hearing-impaired having difficulties in recognizing language due to nerves and brains is rare.

Large sound from apparatuses using earphones or headphones often put a burden on the ears and causes uncomfortable sound for the same reason as the hearing aids.

### SUMMARY OF INVENTION

### Problems to be Solved by Invention

The present disclosure is suggested to address the above-described conventional problems, and for example, achieves the following issues.

1) audio equipment that reproduce sound by earphones and headphones that can be heard like actual sound which is directly heard can be achieved.

2) audio equipment that can reproduce relatively large volume with small output, that is, loudness equivalent to that of products having amplifier output of four times as much can be achieved by the amplitude limiting circuit of the present disclosure.

3) inexpensive hearing aids that enables severe hearing-impaired to talk easily can be provided.

The amplitude limiting circuit of the present disclosure is characteristic in that “an output signal of the reproduced sound does not distort even when a large level signal is input and wave height of the output signal is limited”. Furthermore, when a sound signal in which large sound and small sound are mixed is input, the small sound signal is output from an output circuit as it is, and the large sound signal is output in a level limited by the amplitude limiting circuit. In addition, the output signal of the reproduced sound does not distort much even when the small level signal is amplified to a limit level.

### Means to Solve the Problem

An amplitude limiting circuit for sound signals of the present disclosure includes the following configuration. By an integrator provided in an output circuit, operate as a limiter by outputting a signal in which an upper portion of a wave is logarithmically compressed when signal potential is changed in a plus direction and outputting a signal in which a lower portion of the wave is logarithmically compressed when the signal potential is changed in a minus direction. In addition, the integrator of the output circuit erases, a harmonic produced by an operation of the limiter.

The present disclosure may implement the following configuration. The present disclosure may include:

a limiter which limits amplitude of an input sound signal;

a first integrator which is connected to an output-side of the limiter and which logarithmically compresses a rise level or a fall level of an output signal waveform from the limiter;

a first subtractor which subtracts the output signal from the limiter and the input sound signal;

a second integrator which attenuates a high range of the input sound signal and delays a phase of the input sound signal; and

a second subtractor which is connected to an output-side of the first integrator and an output-side of the second integrator, and which subtracts an output signal of the first integrator and an output signal of the second integrator.

### Effect of Invention

Qualities of livestreaming, remote working, and telemedicine, etc., can be significantly improved by using the amplitude limiting circuit for sound signal of the present disclosure, because users can hear realistic sound from earphones or headphones of playback equipment as if the users are in the recording environment. Furthermore, since the user can comfortably hear large sound and small sound at the same time by a hearing aid of the present disclosure, severe hearing-impaired whom conventional hearing aids cannot assist can enter the world of language. In addition, even apparatuses such as stationary-type speakers would be highly effective in improving performance of sound equipment.

### BRIEF DESCRIPTION OF DRAWINGS

FIG. 1 is a block diagram using as a loudspeaker a first embodiment of an amplitude limiting circuit for sound signal according to the present disclosure.

FIG. 2 is a block diagram illustrating a configuration of a first embodiment of the present disclosure.

FIG. 3 is a block diagram illustrating a configuration of a second embodiment of the present disclosure.

### EMBODIMENTS

### 1. First Embodiment

### [1-1. Configuration of First Embodiment]

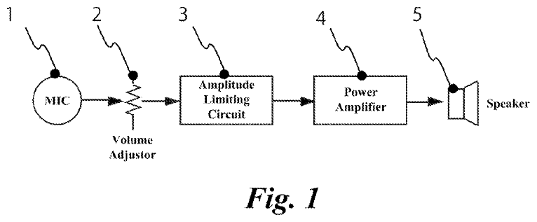

FIG. 1 is a block diagram of a loudspeaker using an amplitude limiting circuit of the present embodiment. As illustrated in FIG. 1, in the present embodiment, an amplitude limiting circuit 3 is provided between a microphone 1 and a power amplifier 4. Note that a volume adjuster 2 is provided after the microphone 1, and a speaker 5 is provided at an output-side of the power amplifier 4. By this configuration, loudness more than the original performance of the power amplifier 4 can be obtained.

Also, this configuration can be applied directly to devices for the hearing-impaired such as hearing aids.

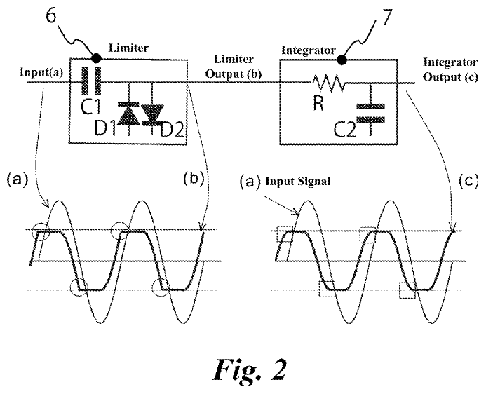

FIG. 2 is a block diagram illustrating a configuration of a first embodiment of the present embodiment. The amplitude limiting circuit of the present embodiment includes a limiter 6 provided at an input-side of a sound signal and an integrator 7 provided at an output-side of limiter 6. The limiter 6 includes a capacitor C1 and diodes D1 and D2 connected to the capacitor C1. The integrator 7 includes a resistance R to which an output signal from the limiter 6 is input and a capacitor C2 provided after the resistance R.

In the amplitude limiting circuit having such a configuration, when there is no input signal, direct current potential of a cathode of the diode D1 or an anode of the diode D2 is 0 V that is the same as GND. However, when a signal with an amplitude larger than forward voltage of the diodes D1 or D2, such as (a) waveform is input to the input, current flows through the diodes D1 and D2, and an output signal amplitude is limited as (b) waveform. At this time, the capacitor C1 is charged or discharged. Voltage at both end of the capacitor C1 is changed by this charging and discharging. This voltage is bias voltage of the output from the limiter 6. That is, when the bias voltage of the limiter 6 changes by large input signal, an output amplitude is limited as (b) signal.

In the amplitude limiting circuit, information loss of portions exceeding a limit amplitude is very small. However, distortion does occur. Therefore, reproduced sound of the (b) waveform has distortion. This distortion is due to harmonics produced along with a change in a level of a circled portion in the waveform.

A time constant of the integrator 7 in FIG. 2 forms rise and fall of the (b) waveform into logarithmic compression waveform to make gentle waveform which has few rapid level change like a squared portion in (c) waveform output from the integrator 7, and at the same time, limits the amplitude. That is, when potential of the input signal is changed in the plus direction, the integrator 7 outputs a signal in which an upper portion of the wave is logarithmically compressed, and when potential of the input signal is changed in the minus direction, the integrator 7 outputs a signal in which a lower portion of the wave is logarithmically compressed. Furthermore, the integrator 7 functions as a high cut filter and eliminates the harmonics included in the output from the integrator 7 produced by the amplitude limitation. That is, the integrator 7 has two functions of logarithmic compression and harmonic elimination. The output signal of this circuit can reproduce sufficiently large sound even when the sound is in the level in which the sound pressure by earphones and earholes hardly increases.

For the integrator 7 to have the above-described functions, the time constant (C2 and R) must be appropriately selected. The correct calculation of the time constant of the integrator 7 as described above is difficult, because sizes of earholes differ for each person. However, the time constant causes less problem even when it is relatively short. It is because distortion at low frequency does not largely affect the sound quality.

[1-2. Action and Effect of First Embodiment]

Products which the user can comfortably hear both large sound and small sound at the same time can be manufactured by using in the hearing aid the amplitude limiting circuit of the first embodiment having the above structure. Furthermore, the maximum volume would be the upper limit output from the hearing aid. Therefore, theoretically, when the maximum acoustic output from the hearing aid is 120 dB/spl, the hearing-impaired of 116 dB/spl can hear sound of 0 dB/spl. In addition, if this amplitude limiting circuit is used in a recording/playback machine, it is possible to play back small sounds that are caused by distant sound sources, etc., without being disturbed by nearby loud sound.

In the present embodiment, since rise or fall of large sound is logarithmically compressed and the amplitude thereof is limited, excessively large sound would not be reproduced at circuit gain in which this level does not cause the pressure increase by earphones and earholes. Furthermore, power to drive earphones is less than a case in which logarithmic compression is not performed, and the reproduced sound with excellent low sound characteristic and strong power can be obtained even by equipment with small output. That is, when square wave is input in the integrator circuit, waveform with round corners is output. This is because high frequency component is attenuated, however, since deterioration of the reproduced sound due to this is very small, it would not be a problem. In addition, these round corners are logarithmic, and if harmonics due to the amplitude limitation is not included in the output signal from the integrator circuit, it is a limiter with excellent logarithmic compression characteristic. Note that is well-known for the one skilled in the art that the integrator circuit also functions as the high cut filter.

Furthermore, since the sound signal in which the amplitude is limited by the circuit of the present invention can be reproduced with relatively large loudness even without large amplitude signal, it is advantageous for stationary-type speakers. The output signal from the circuit illustrated in FIG. 2 is not suitable for a hi-fi because high frequency component is eliminated by the integrator 7. However, it is practical for equipment that does not require broad frequency band so much.

### 2. Second Embodiment

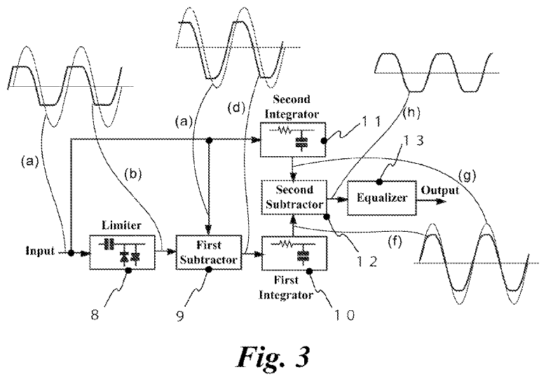

A second embodiment illustrated in FIG. 3 is an example configuration of an amplitude limiting circuit for a hi-fi. Although broad frequency characteristic is required for hi-fi equipment, the circuit configuration of FIG. 2 presented in the first embodiment cannot achieve preferable frequency characteristic because the high frequency component is eliminated by the integrator 7. FIG. 3 is a block diagram of the second embodiment which addresses the above problem, and achieves much broader frequency characteristic compared to the circuit in FIG. 2. For example, the frequency characteristic of the circuit in FIG. 2 is <5 kHz, whereas the frequency characteristic of the circuit in FIG. 3 is 40 kHz or more. This limited output signal can reproduce sufficiently large sound even when the sound is in the level in which the sound pressure by earphones and earholes hardly increases.

In the second embodiment, a first subtractor 9 is provided between a limiter 8 to process an input signal and a first integrator 10. The input signal is input to the first subtractor 9 together with the output signal from the limiter 8, and the first subtractor 9 subtraction process is performed to both signals. Furthermore, other than the first integrator 10, a second integrator 11 to process the input signal and a second subtractor 12 to subtract outputs from the first integrator 10 and the second integrator 11 are provided. The output signal from the second subtractor 12 is output from the power amplifier 4 and the speaker 5 via an equalizer 13.

In the second embodiment, an input signal (a) is input to each of the limiter 8, the first subtractor 9, and the second integrator 11. Similarly to the limiter 6 in FIG. 2, wave height limitation is performed and a signal with (b) waveform is produced in the limiter 8, and an output signal (b) of the limiter 8 is subtracted from the input signal (a) in the first subtractor 9. An output signal (d) of the first subtractor 9 is input to the first integrator 10 and becomes a signal (f) in which fall and rise of the waveform are adjusted by logarithmic characteristic. The frequency component is eliminated from the output signal (f) from the first integrator 10.

Meanwhile, one of the input signal (a) is input to the second integrator 11, and the high frequency range of the input signal (a) is attenuated and the phase of the input signal (a) is delayed. A reason to attenuate and delay an output signal (g) from the second integrator 11 is to match the characteristic of the output signal (g) with the characteristic of the output signal (d) of the first subtractor 9 that is the one of the other signal input to the second subtractor 12. An output signal (h) of the second subtractor 12 expresses waveform similar to the output signal of the integrator 7 in FIG. 2. However, since the output from the integrator 7 includes harmonic caused by the wave height limitation, when said signal is reproduced by emphasizing the high frequency range, the sound distorts. However, the output signal (h) of the second subtractor 12 does not include harmonic caused by the wave height limitation.

A reason why harmonic is not included is because the output signal (h) of the second subtractor 12 is a result of subtracting the output signal (f) of the first integrator 10 from the output signal (g) of the second integrator 11 and because most of said component is a part of the input signal which does not include distortion. Therefore, even when high frequency range of the output signal (h) of the second subtractor 12 is emphasized, distortion would not be heard from the reproduced sound.

[2-2. Action and Effect of Second Embodiment]

According to the configuration of the second embodiment, an output signal for hi-fi equipment that does not include harmonic caused by wave height limitation while having broad frequency characteristic can be obtained.

### INDUSTRIAL APPLICABILITY

The present disclosure can be applied to recording, reproduction, or transmission of natural sound and can be applied to sound information equipment such as remote working and livestreaming.

### REFERENCE SIGN

1: microphone
2: volume adjustor
3: amplitude limiting circuit
4: power amplifier
5: speaker
6: limiter
7: integrator
8: limiter
9: subtractor
10: integrator
11: integrator
12: subtractor
13: equalizer
C1, C2: capacitor
R: resistance
D1, D2: diode

What is claimed is:

1. An amplitude limiting circuit for sound signal, operating as a limiter by outputting a signal in which an upper portion of a wave is logarithmically compressed when a signal potential is changed in a plus direction and outputting a signal in which a lower portion of the wave is logarithmically compressed when the signal potential is changed in a minus direction, and having an integrator functioning as a high cut filter in an output circuit.

2. An amplitude limiting circuit for sound signal, comprising:
a limiter which limits an amplitude of an input sound signal;
a first integrator which is connected to an output-side of the limiter and which logarithmically compresses a rise level or a fall level of an output signal waveform from the limiter;
a first subtractor which subtracts the output signal from the limiter and the input sound signal;
a second integrator which attenuates a high range of the input sound signal and delays a phase of the input sound signal; and
a second subtractor which is connected to an output-side of the first integrator and an output-side of the second integrator, and which subtracts an output signal of the first integrator and an output signal of the second integrator.
